(19) United States
(12) Patent Application Publication
(10) Pub. No.: US 2025/0364061 A1
(43) Pub. Date: Nov. 27, 2025

(54) MULTI-STEP ANALOG PROGRAM CONVERGENCE FOR MEMORY CELLS IN A MEMORY DEVICE

(71) Applicant: Micron Technology, Inc., Boise, ID (US)

(72) Inventors: Eric N. Lee, San Jose, CA (US); Huai-Yuan Tseng, San Ramon, CA (US); Koichi Kawai, Yokohama (JP); Yoshihiko Kamata, Yokohama (JP); Lawrence Celso Miranda, San Jose, CA (US); Akira Goda, Tokyo (JP)

(21) Appl. No.: 19/195,502

(22) Filed: Apr. 30, 2025

Related U.S. Application Data
(60) Provisional application No. 63/650,344, filed on May 21, 2024.

(51) Int. Cl. G11C 16/34; G11C 16/04; G11C 16/10

(52) U.S. Cl. CPC G11C 16/3459; G11C 16/0483; G11C 16/102

(57) ABSTRACT

Control logic in a memory device initiates a program operation on a memory array of a memory device, the memory array comprising a plurality of memory cells, and the program operation comprising a plurality of program pulses. The control logic further identifies a first subset of the plurality of memory cells and a second subset of the plurality of memory cells based on respective threshold voltages after application of a first program pulse of the plurality of program pulses, and boosts a voltage potential in one or more pillars of the memory array corresponding to the first subset of the plurality of memory cells prior to application of a second program pulse of the plurality of program pulses.

### RELATED APPLICATIONS

This application claims the benefit of priority from U.S. Provisional Patent Application No. 63/650,344 filed May 21, 2024, the entire contents of which are hereby incorporated by reference herein.

### TECHNICAL FIELD

Embodiments of the disclosure relate generally to memory sub-systems, and more specifically, relate to multi-step analog program convergence for memory cells in a memory device of a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system in accordance with some embodiments of the present disclosure.

FIG. 1B is a block diagram of a memory device in communication with a memory sub-system controller of a memory sub-system, in accordance with some embodiments of the present disclosure.

FIG. 2 is a schematic of portions of an array of memory cells as could be used in a memory of the type described with reference to FIG. 1B in accordance with some embodiments of the present disclosure.

FIG. 3 is a flow diagram of an example method of multi-step analog program convergence for memory cells in a memory device of a memory sub-system in accordance with some embodiments of the present disclosure.

FIG. 4A is a graph illustrating a program distribution for a number of memory cells intended to be programmed to a given program level (i.e., state) in accordance with some embodiments of the present disclosure.

FIG. 4B is a graph illustrating the data line bias voltages applied to different memory cells during analog program converge in accordance with some embodiments of the present disclosure.

FIG. 5 is a flow diagram of an example method of multi-step analog program convergence for memory cells in a memory device of a memory sub-system in accordance with some embodiments of the present disclosure.

FIG. 6 is a diagram illustrating the various signals applied during multi-step analog program convergence in accordance with some embodiments of the present disclosure.

FIG. 7 is a block diagram of an example computer system in which embodiments of the present disclosure can operate.

### DETAILED DESCRIPTION

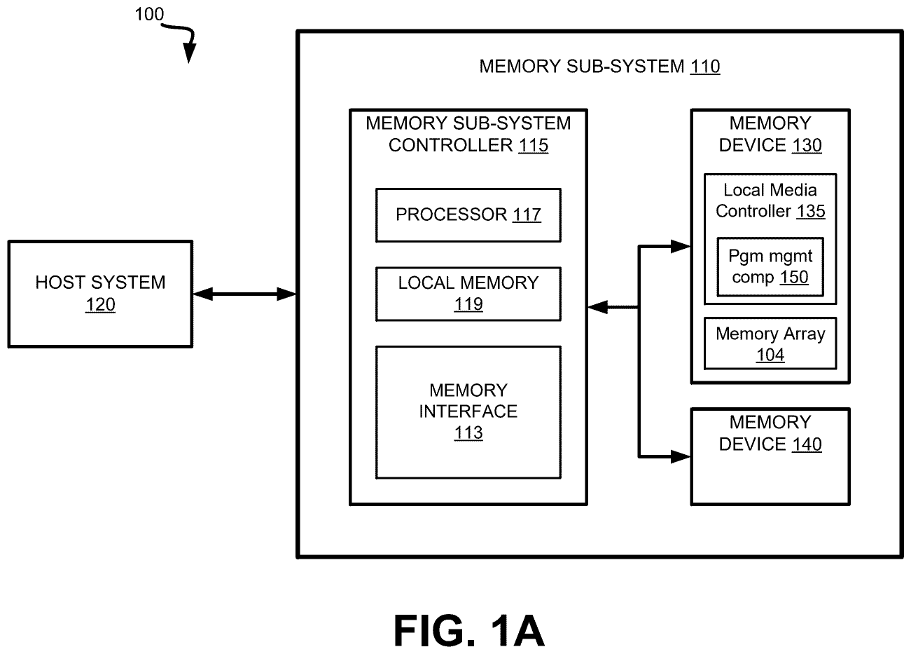

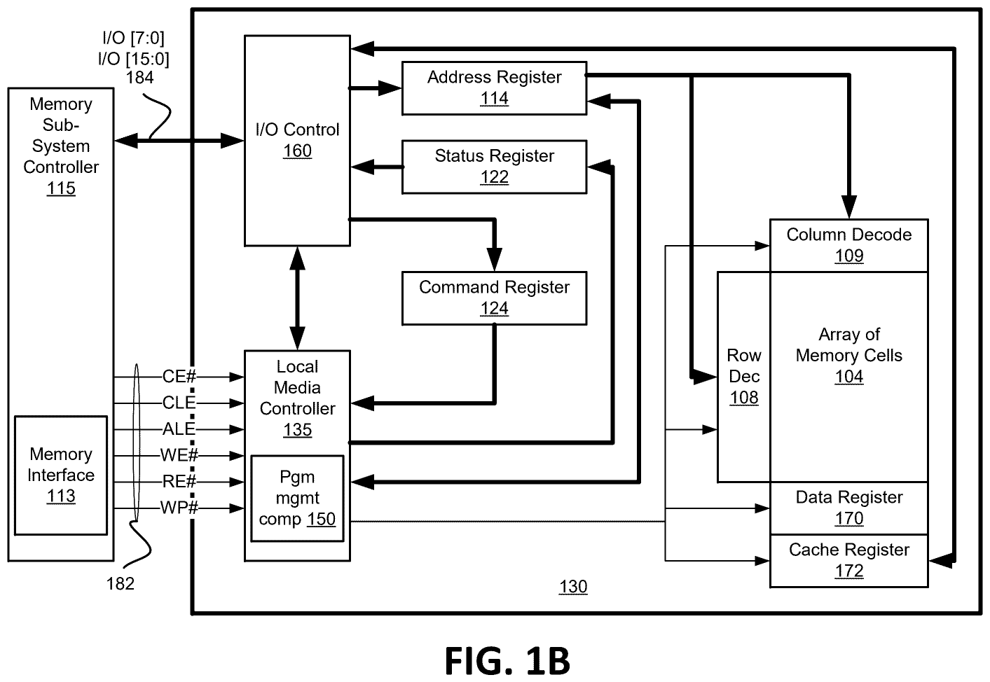

Aspects of the present disclosure are directed to multi-step analog program convergence for memory cells in a memory device of a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more dice, each including one or more planes. For some types of non-volatile memory devices (e.g., NAND memory), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

Programming of a memory device can be accomplished by applying one or more programming pulses, separated by verify pulses, to program each memory cell of a selected group of memory cells to a respective target data state (which may be an interim or final data state). In such an approach, the programming pulses are applied to access lines, such as those typically referred to as wordlines, for the selected memory cells. After each programming pulse, one or more verify voltage levels are typically used to verify the programming of the selected memory cells. Programming typically uses many programming pulses in an incremental step pulse programming (ISPP) scheme, where each programming pulse is a single-level pulse that moves the memory cell threshold voltage by some amount.

The programming pulses can be applied to a selected access line (e.g., wordline) and thus to the control gates of the row of memory cells connected to the selected access line (e.g., having their control gates connected to the selected access line). Typical programming pulses might start at or near 13V and tend to increase in magnitude for each subsequent programming pulse application. While the program potential (e.g., voltage level of the programming pulse) is applied to the selected access line, an enable voltage, such as a reference potential (e.g., 0V), might be applied to the channels of memory cells selected for programming (i.e., those memory cells for which the programming operation is intended to shift their data state to some higher level). This can result in a charge transfer from the channel to the charge storage structures of these selected memory cells. For example, floating gates are typically charged through direct injection or Fowler-Nordheim tunneling of electrons from the channel to the floating gate, resulting in an increased threshold voltage in a programmed state.

During programming, an inhibit voltage (e.g., Vcc) can be applied to data lines (e.g., bitlines) which are selectively connected to a string of memory cells, including a memory cell that is connected to the selected access line and is not selected for, or is no longer selected for, programming. In addition to data lines selectively connected to memory cells already at their target data state, these unselected data lines might further include data lines that are not addressed by the programming operation. For example, a logical page of data might correspond to memory cells connected to a particular access line and selectively connected to some particular subset of the data lines (e.g., every other data line), such that the remaining subset of data lines would be unselected for the programming operation and thus inhibited.

Between the application of one or more programming pulses, a verify phase of the programming operation can be performed to check each selected memory cell to determine if it has reached a target data state. If a selected memory cell has reached the target data state, it can be inhibited from further programming if there remain other selected memory cells still requiring additional programming pulses to reach their target data states. Following a verify phase, an additional programming pulse might be applied if there are memory cells that have not completed programming. This process of applying a programming pulse followed by verification (e.g., a programming phase and a verify, or sensing, phase of a programming operation) typically continues until all the selected memory cells have reached their target data states. If a particular number of programming pulses (e.g., maximum number) have been applied, or a particular voltage level of a programming pulse (e.g., maximum voltage level) has been reached, and one or more selected memory cells still have not completed programming, those memory cells might be marked as defective, for example.

The use of different voltage levels on data lines to be enabled for programming might occur in programming schemes known as selective slow programming convergence (SSPC), where memory cells nearer to their respective target data states are programmed more slowly (e.g., partially enabled for programming) compared to memory cells farther from their respective target data states (e.g., fully enabled for programming) while receiving a same voltage level at their respective control gates. SSPC programming schemes can facilitate more narrow distributions of threshold voltages defining each data state over more traditional programming schemes that rely on memory cells being either fully enabled or inhibited from programming. By narrowing the threshold voltage distributions, and thus providing more dead space, or margin, between adjacent threshold voltage distributions, accuracy of determining data states of memory cells can be improved and/or memory density (e.g., number of digits of data per memory cell) can be increased.

Although SSPC programming schemes can provide for tighter threshold voltage distributions over more traditional programming schemes, that benefit typically comes with a cost. In particular, memory cells subject to the programming operation are generally apportioned to different subsets of memory cells for each programming pulse (e.g., one subset of memory cells to be inhibited from programming, one subset of memory cells to be fully enabled for programming, and one subset of memory cells for partial enablement of programming). Each subset of memory cells corresponds to a respective, mutually exclusive, range of threshold voltages. The threshold voltage for each memory cell subject to the programming operation is generally determined or estimated in order to apportion it to the proper subset of memory cells. This can add time and/or complexity to the verify phase of the programming operation.

Various approaches seek to facilitate further narrowing of threshold voltage distributions over typical SSPC programming schemes, while mitigating a need to apportion memory cells for each level of partial enablement of programming. Such approaches can provide a data line voltage level during a subsequent programming pulse that is inversely related to its corresponding memory string current level (e.g., I_{string}) during a verify phase of the programming operation (e.g., an immediately prior verify phase of the programming operation). Control logic in the memory device may capture a retained voltage level of a node of a page buffer circuit following or during a verify phase of the programming operation. During the verify phase of the programming operation, the node might be precharged, and then selectively discharged through a data line responsive to a level of activation of a selected memory cell of a programming operation. As such, a memory cell having a higher threshold voltage (e.g., lower I_{string} in response to a given control gate voltage level) might be expected to result in a higher retained voltage level at the node than a memory cell having a lower threshold voltage (e.g., higher I_{string} in response to the given control gate voltage level). The remaining voltage level of the node might subsequently be used as a control voltage of a source-follower to generate a data line voltage level for a subsequent programming operation. In this manner, memory cells closer to their target threshold voltage might be expected to receive a higher data line voltage (e.g., a lower level of partial enablement) and memory cells farther from their target threshold voltage might be expected to receive a lower data line voltage (e.g., higher level of partial enablement). The result is an analog program convergence approach, where the data line voltage varies depending on the threshold voltage of the selected memory cell, rather than using a digital program convergence approach (e.g., where cells are either fully enabled for programming, partially enabled for programming, or inhibited).

These analog approaches suffer from a number of drawbacks, however. For optimal operation, the memory device needs to generate a large range of voltages to bias the data line in order to achieve the different levels of partial enablement during programming. Achieving the requisite range of bias voltages can be challenging, however, due to a number of factors including, a limited window for the control signal of a drain-side select gate device (SGD) in the memory string, a limited window for the cell current (Icell) versus the threshold voltage, and variations present in the string current (Istring). For example, the maximum bias voltage that can be achieved is limited by the on-off window of an SGD transistor. Accordingly, the bias voltage needs to be low enough to be driven into the pillar, while at the same time, the inhibit bias (VCC) needs to be high enough to ensure the pillar is cutoff for boosting. In addition, if the window where Icell is not saturated with respect to the threshold voltage or the gate bias is less than a threshold voltage range of interest, then conversion of Icell to the bitline bias voltage can not be achieved across the desired range. Furthermore, variations in string current further reduce the useful Icell vs threshold voltage window.

Aspects of the present disclosure address the above and other deficiencies by implementing multi-step analog program convergence for memory cells in a memory device of a memory sub-system. In one embodiment, the range of data line bias voltages to be used for analog program convergence can be divided into two or more steps corresponding to different sets of memory cells for which different levels of partial enablement are appropriate. For example, one step can correspond to a first set of memory cells closer to their target threshold voltage (i.e., thus requiring a larger data line bias) and another step can correspond to a second set of memory cells farther from their target threshold voltage (i.e., thus requiring a smaller data line bias). In one embodiment, control logic of the memory device can boost the pillars of the memory device corresponding to the memory cells in the first set during programming to increase the data line bias for those memory cells. Accordingly, a larger range of data line bias voltages is available so that more levels of partial enablement can be achieved during programming.

Advantages of this approach include, but are not limited to, improved performance in the memory sub-system. The approach described herein allows for a larger range of data line bias voltages to be achieved without requiring additional voltage generation circuitry. The larger range of data line bias voltages ensures that analog program convergence techniques can be applied more accurately to memory cells at varying distances from their target voltages, which reduces program latency.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the physical host interface (e.g., PCIe or CXL interface). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, the memory sub-system 110 includes a memory interface 113 that is responsible for handling interactions of memory sub-system controller 115 with the memory devices of memory sub-system 110, such as memory device 130. For example, the memory interface 113 can send memory access commands corresponding to requests received from host system 120 to memory device 130, such as program commands, read commands, or other commands. In addition, the memory interface 113 can receive data from memory device 130, such as data retrieved in response to a read command or a confirmation that a program command was successfully performed. In some embodiments, the memory sub-system controller 115 includes at least a portion of the memory interface 113. For example, the memory sub-system controller 115 can include a processor 117 (processing device) configured to execute instructions stored in local memory 119 for performing the operations described herein.

In one embodiment, local media controller 135 of memory device 130 includes program convergence management component 150. Program convergence management component 150 can manage programming convergence associated with the memory cells in memory array 104 of memory device 130. For example, program convergence management component 150 can implement multi-step analog program convergence for the memory cells in memory array 104. In one embodiment, program convergence management component 150 can divide the range of data line bias voltages to be used for analog program convergence into two or more steps corresponding to different sets of memory cells for which different levels of partial enablement are appropriate. For example, one step can correspond to a first set of memory cells closer to their target threshold voltage (i.e., thus requiring a larger data line bias) and another step can correspond to a second set of memory cells farther from their target threshold voltage (i.e., thus requiring a smaller data line bias). In one embodiment, program convergence management component 150 can boost the pillars of the memory array 104 corresponding to the memory cells in the first set during programming to increase the data line bias for those memory cells, so that a larger range of data line bias voltages is available allowing more levels of partial enablement to be achieved during programming. Further details with regards to the operations of program convergence management component 150 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. In one embodiment, memory sub-system controller 115 includes memory interface 113.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses. In one embodiment, local media controller 135 includes program management component 150, which can implement multi-step analog program convergence for memory cells in memory array 104, as described herein.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

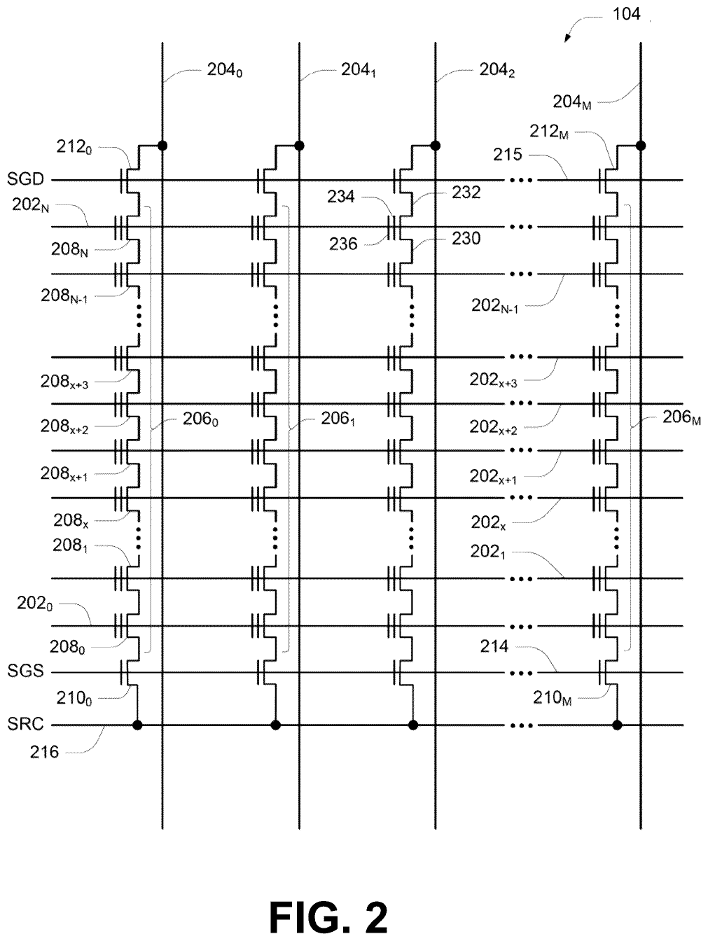

FIG. 2 is a schematic of portions of an array of memory cells 104, such as a NAND memory array, as could be used in a memory of the type described with reference to FIG. 1B according to an embodiment. Memory array 104 includes access lines, such as wordlines 2020 to 202N, and data lines, such as bit lines 2040 to 204M. The wordlines 202 can be connected to global access lines (e.g., global wordlines), not shown in FIG. 2, in a many-to-one relationship. For some embodiments, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bit line 204 for the corresponding NAND string 206. For example, the drain of select gate 2120 can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 104 in FIG. 2 can be a quasi-two-dimensional memory array and can have a generally planar structure, e.g., where the common source 216, NAND strings 206 and bit lines 204 extend in substantially parallel planes. Alternatively, the memory array 104 in FIG. 2 can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bit line 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202N and selectively connected to even bit lines 204 (e.g., bit lines 2040, 2042, 2044, etc.) can be one physical page of the memory cells 208 (e.g., even memory cells) while memory cells 208 commonly connected to wordline 202N and selectively connected to odd bit lines 204 (e.g., bit lines 2041, 2043, 2045, etc.) can be another physical page of the memory cells 208 (e.g., odd memory cells).

Although bit lines 2043-2045 are not explicitly depicted in FIG. 2, it is apparent from the figure that the bit lines 204 of the array of memory cells 104 can be numbered consecutively from bit line 2040 to bit line 204M. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 2020-202N (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

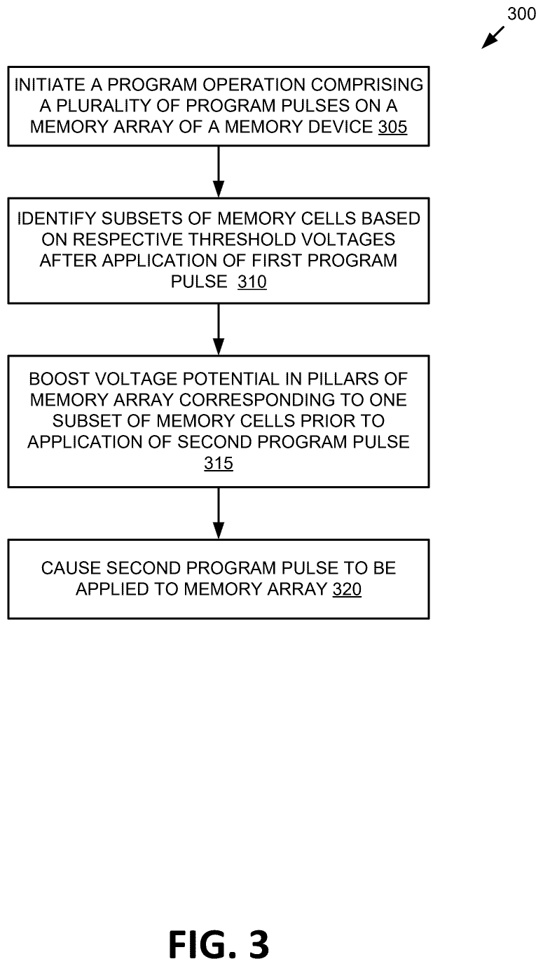

FIG. 3 is a flow diagram of an example method of multi-step analog program convergence for memory cells in a memory device of a memory sub-system in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by program convergence management component 150 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 305, a program operation is initiated. For example, the processing logic (e.g., program convergence management component 150) can initiate a program operation on the memory array, the program operation comprising a plurality of program pulses. In one embodiment, each of the program pulses are separated by verify pulses, and are applied to access lines (e.g., wordlines) associated with selected memory cells to program the selected memory cells to a respective target data states. After each program pulse, one or more verify voltage levels are typically used to verify the programming of the selected memory cells. Programming typically uses many programming pulses in an incremental step pulse programming (ISPP) scheme, where each programming pulse is a single-level pulse that moves the memory cell threshold voltage by some amount.

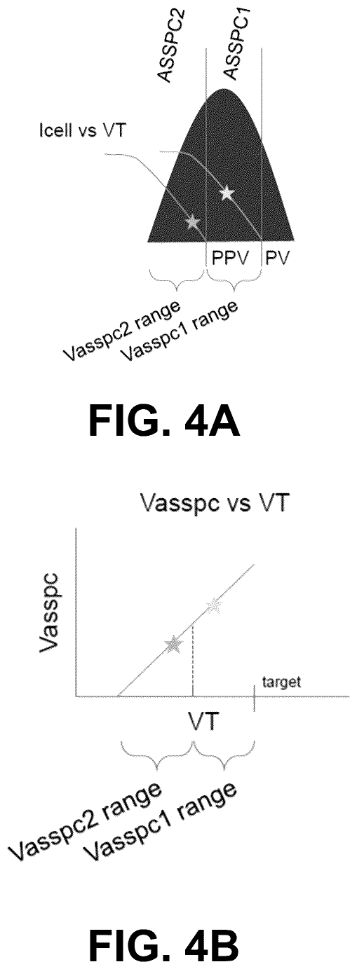

At operation 310, subsets of memory cells are identified. For example, the processing logic identifies a first subset of the plurality of memory cells and a second subset of the plurality of memory cells based on respective threshold voltages after application of a first program pulse of the plurality of program pulses. In one embodiment, after each program pulse is applied, a program verify pulse can be applied to determine the respective threshold voltages of each memory cell associated with a given wordline. Program convergence management component 150 can compare the respective threshold voltages to a number of thresholds, such as a program verify (PV) threshold, which can represent the target voltage to which the memory cell is intended to be programmed, and a pre-program verify (PPV) threshold, which can be a voltage level that is a certain amount lower than the program verify threshold. An example of these subsets is illustrated in FIG. 4A. FIG. 4A is a graph illustrating a program distribution for a number of memory cells intended to be programmed to a given program level (i.e., state) in accordance with some embodiments of the present disclosure. After the application of a prior program pulse, a certain number of memory cells in the distribution may have reached a threshold voltage that is greater than or equal to the program verify (PV) threshold, and thus do not need to be programmed any further. The processing logic can identify a first subset of memory cells having threshold voltages that are less than the program verify (PV) threshold but greater than the pre-program verify (PPV) threshold. In FIG. 4A, this first subset can include the memory cells in the range labeled “ASSPC1.” The processing logic can identify a second subset of memory cells having threshold voltages that are less than the pre-program verify (PPV) threshold. In FIG. 4A, this second subset can include the memory cells in the range labeled “ASSPC2.” In other embodiments, there can be some other number of subsets and/or the subsets of memory cells can be identified using different or additional criteria. The Icell vs threshold voltage (VT) curves represent the cell current being drawn by the string in response to a gate bias (e.g., PPV or PV). For example, if a cell had a VT position at the PV threshold, the Icell would be low. As this cell VT moves lower, the corresponding cell current would increase with some relation to the VT.

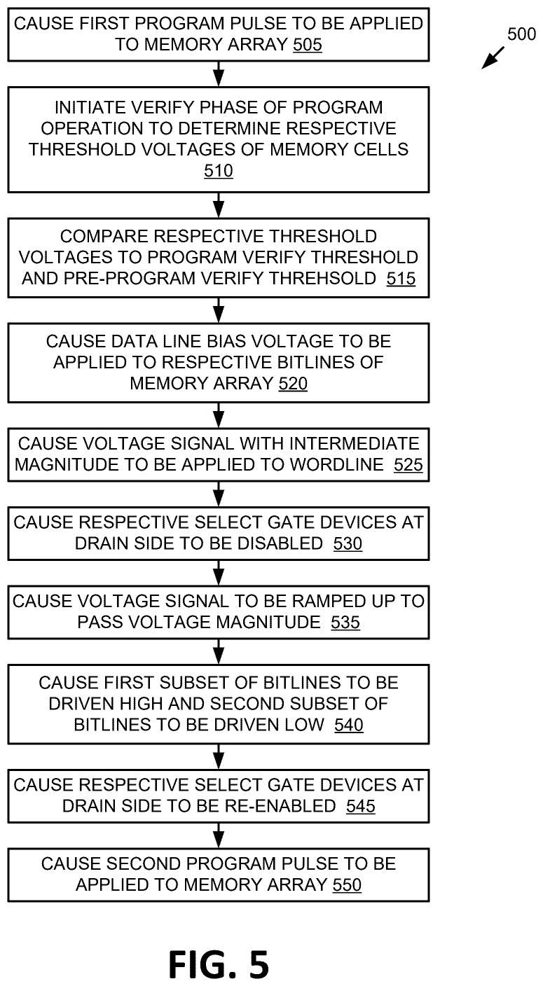

Referring again to FIG. 3, at operation 315, a pillar voltage potential is boosted. For example, the processing logic boosts a voltage potential in one or more pillars of the memory array corresponding to the first subset of the plurality of memory cells prior to application of a second program pulse of the plurality of program pulses. Boosting the voltage in the pillars corresponding to the first subset of the plurality of memory cells (i.e., those memory cells that are closer to the target program voltage) will increase the effective data line bias voltages (Vaaspc) for the first subset of the plurality of memory cells, as shown in FIG. 4B. FIG. 4B is a graph illustrating the data line bias voltages applied to different memory cells during analog program converge in accordance with some embodiments of the present disclosure. In one embodiment, a voltage supply in the memory sub-system 110 may be configured to provide a range of data line bias voltages (Vasspc) for memory cells having threshold voltages (VT) that fall within the Vasspc2 range. In order to increase the effective data line bias voltages for those memory cells having threshold voltages (VT) that fall within the Vasspc1 range, program convergence management component 150 boost the voltage potential in the corresponding pillars, as is described in more detail below with respect to operation 500 of FIG. 5.

Referring again to FIG. 3, at operation 320, a program pulse is applied. For example, the processing logic causes a second program pulse to be applied to the memory array 104. When the second program pulse is applied to a selected wordline, the level of partial program enablement can be controlled by the differences in the bitline bias voltages applied to different memory cells, including the higher effective bitline bias voltages applied to those memory cells in the Vasspc1 range. As a result, memory cells closer to their target threshold voltage can receive a higher data line bias voltage (e.g., a lower level of partial enablement) and thus will be programmed more “slowly” and memory cells farther from their target threshold voltage can receive a lower data line bias voltage (e.g., higher level of partial enablement) and thus will be programmed less “slowly.”

FIG. 5 is a flow diagram of an example method of multi-step analog program convergence for memory cells in a memory device of a memory sub-system in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by program convergence management component 150 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 505, a program pulse is applied. For example, the processing logic (e.g., program convergence management component 150) can cause a first program pulse, of a plurality of program pulses associated with a program operation, to be applied to a memory array 104 of a memory device, such as memory device 130. In one embodiment, the first program pulse is applied to a selected wordline of memory array 104 associated with one or more memory cells to be programmed to certain program levels (e.g., states).

At operation 510, a verify phase of the program operation is initiated. For example, the processing logic can initiate a verify phase of the program operation to determine respective threshold voltages of the plurality of memory cells after application of the first program pulse. In one embodiment, after each program pulse is applied, a program verify pulse can be applied to determine the respective threshold voltages of each memory cell associated with the selected wordline.

At operation 515, a comparison is performed. For example, the processing logic can compare the respective threshold voltages to a program verify (PV) threshold level and a pre-program verify (PPV) threshold level. As illustrated in FIG. 4A, the processing logic can identify a first subset of memory cells in the range labeled “ASSPC1” having threshold voltages that are less than the program verify (PV) threshold but greater than the pre-program verify (PPV) threshold. The processing logic can further identify a second subset of memory cells in the range labeled “ASSPC2” having threshold voltages that are less than the pre-program verify (PPV) threshold.

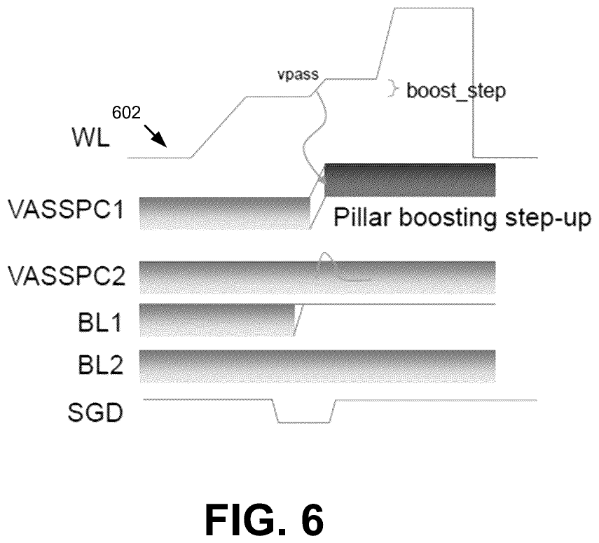

At operation 520, a data line bias voltage is applied. For example, the processing logic can cause a data line bias voltage to be applied to a plurality of respective bitlines corresponding to the plurality of memory cells. This data line bias voltage (Vasspc) can be any of a number of voltage magnitudes that are able to be generated by a voltage source in the memory sub-system 110. In one embodiment, the data line bias voltage applied to the data lines corresponding to the first subset of memory cells (i.e., BL1 and represented by VASSPC1) and the data line bias voltage applied to the data lines corresponding to the second subset of memory cells (i.e., BL2 and represented by VASSPC2) are initially of the same magnitude, as shown in FIG. 6. FIG. 6 is a diagram illustrating the various signals applied during multi-step analog program convergence in accordance with some embodiments of the present disclosure. It should be noted that in FIG. 6, the signals BL1 and BL2, and the corresponding effective data line bias voltage levels VASSPC1 and VASSPC2, are illustrated as gradient bars to indicate that the actual data line bias voltage corresponding to each individual memory cell can be any voltage magnitude within a certain range, and that the data line bias voltages applied to different memory cells can vary according to the analog nature of the algorithm (e.g., based on the different cell currents (Icell)). In one embodiment, the processing logic performs a current integration of Icell onto a capacitor. This capacitor can be initially precharged to some level and subsequently discharged with a current equal to Icell for a specific time interval. Afterwards, the discharged voltage on the capacitor is proportional to Icell. Thus, for a cell with low Icell, this capacitor voltage is higher, while a cell with high Icell has a lower capacitor voltage. The voltage is then transferred to the gate of a source-follower driver which drives this bias onto the bitline during the program pulse phase, where the bias is inversely proportional to Icell.

Referring again to FIG. 5, at operation 525, a voltage signal is applied to a wordline. For example, the processing logic can cause a voltage signal to be applied to a wordline associated with the plurality of memory cells (i.e., the selected wordline), the voltage signal having an intermediate magnitude. As shown in FIG. 6, the voltage signal 602 can be ramped up from a low voltage (e.g., 0V) to the intermediate voltage, which can be represented as the pass voltage (Vpass) minus a boost step amount (boost_step). The boost step amount is a configurable amount that can vary depending on the implementation.

At operation 530, a select gate device is disabled. For example, the processing logic can cause respective select gate devices (e.g., one or more of select gates 2120 to 212M) at a drain side of the one or more pillars to be disabled. The select gate devices can be disabled via control signal SGD (i.e., by driving the SGD signal low for a period of time). Disabling the select gate devices disconnects the pillars from the corresponding data lines (e.g., bitlines) causing the pillars to float.

At operation 535, the voltage signal is increased. For example, the processing logic can cause the voltage signal 602 applied to the selected wordline to be ramped up to a pass voltage magnitude (Vpass). As described above, the pass voltage magnitude is greater than the intermediate magnitude by the boost step amount (boost_step). The increased magnitude of voltage signal 602 will boost the voltage potential in each of the pillars in the memory array, including those corresponding to memory cells in both the Vasspc1 and Vasspc2 ranges. In FIG. 6, this is illustrated by effective data line bias voltage VASSPC1 being boosted a higher magnitude (i.e., the “Pillar boosting step-up”). It should be noted that the effective data line bias voltage VASSPC2 is also boosted to a higher magnitude, although only temporarily and will be brought back down, as described in more detail below.

At operation 540, bitlines are biased. For example, the processing logic can cause a first subset of the plurality of bitlines associated with the first subset of the plurality of memory cells (i.e., the cells in the Vasspc1 range) to be driven with a high voltage. This is illustrated in FIG. 6 by the signal BL1 being driven to a high state (i.e., greater than the data line bias voltage magnitude at which it was previously). In addition, the processing logic can cause a second subset of the plurality of bitlines associated with the second subset of the plurality of memory cells (i.e., the cells in the Vasspc2 range) to be driven with the original data line bias voltage. This is illustrated in FIG. 6 by the signal BL2 remaining at the same level.

At operation 545, a select gate device is enabled. For example, the processing logic can cause the respective select gate devices to be re-enabled. The select gate devices can be enabled via control signal SGD (i.e., by driving the SGD signal high again). Once the select gate devices are reenabled, the effective data line bias voltage (VASSPC2) for the second subset of memory cells is driven back down to the original magnitude because the signal BL2 remains unchanged. Since the signal BL1 is driven high, however, the effective data line bias voltage (VASSPC1) for the first subset of memory cells remains at the boosted potential level. When the select gate is re-enabled, BL2 is re-driven into the pillar to restore the pillar potential represented by “VASSPC2” back to an originally intended target after being boosted up. The signal BL1 is driven high in order to cut off the pillar intended for the “VASSPC2” level. Thus, when SGD is re-enabled, the pillar remains at the boosted potential. This requires careful control of the boost_step, SGD bias, BL1, and BL2 levels to ensure that the boosted potential for VASSPC1 can be retain while being able to drive VASSPC2 at the same time. Accordingly, a higher range of effective data line bias voltages are available for those memory cells having threshold voltages (VT) that fall within the Vasspc1 range, as illustrated in FIG. 4B.

At operation 550, a program pulse is applied. For example, the processing logic can cause the voltage signal 602 applied to the wordline to be ramped up to a program voltage magnitude corresponding to the second program pulse. When the second program pulse is applied to a selected wordline, the level of partial program enablement can be controlled by the differences in the bitline bias voltages applied to different memory cells, including the higher effective bitline bias voltages applied to those memory cells in the Vasspc 1 range. As a result, memory cells closer to their target threshold voltage can receive a higher data line bias voltage (e.g., a lower level of partial enablement) and thus will be programmed more “slowly” and memory cells farther from their target threshold voltage can receive a lower data line bias voltage (e.g., higher level of partial enablement) and thus will be programmed less “slowly.”

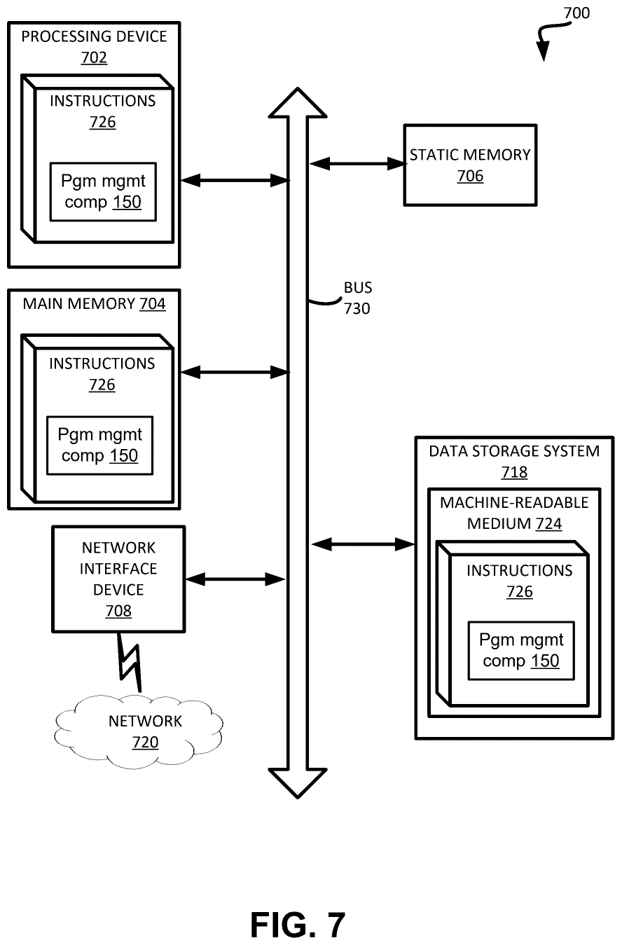

FIG. 7 illustrates an example machine of a computer system 700 within which a set of instructions, for causing the machine to perform any one or more of the methodologies discussed herein, can be executed. In some embodiments, the computer system 700 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to program convergence management component 150 or local media controller 135 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a data storage system 718, which communicate with each other via a bus 730.

Processing device 702 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 702 can also be one or more special-purpose processing devices such as an application specific integrated circuit (ASIC), a field programmable gate array (FPGA), a digital signal processor (DSP), network processor, or the like. The processing device 702 is configured to execute instructions 726 for performing the operations and steps discussed herein. The computer system 700 can further include a network interface device 708 to communicate over the network 720.

The data storage system 718 can include a machine-readable storage medium 724 (also known as a computer-readable medium) on which is stored one or more sets of instructions 726 or software embodying any one or more of the methodologies or functions described herein. The instructions 726 can also reside, completely or at least partially, within the main memory 704 and/or within the processing device 702 during execution thereof by the computer system 700, the main memory 704 and the processing device 702 also constituting machine-readable storage media. The machine-readable storage medium 724, data storage system 718, and/or main memory 704 can correspond to the memory sub-system 110 of FIG. 1A.

In one embodiment, the instructions 726 include instructions to implement functionality corresponding to the program convergence management component 150 of FIG. 1A. While the machine-readable storage medium 724 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of memory cells; and
control logic, operatively coupled with the memory array, to perform operations comprising:
initiating a program operation on the memory array, the program operation comprising a plurality of program pulses;
identifying a first subset of the plurality of memory cells and a second subset of the plurality of memory cells based on respective threshold voltages after application of a first program pulse of the plurality of program pulses; and
boosting a voltage potential in one or more pillars of the memory array corresponding to the first subset of the plurality of memory cells prior to application of a second program pulse of the plurality of program pulses.

2. The memory device of claim 1, wherein identifying the first subset of the plurality of memory cells and the second subset of the plurality of memory cells comprises initiating a verify phase of the program operation to determine the respective threshold voltages and comparing the respective threshold voltages to a program verify threshold level and a pre-program verify threshold level.

3. The memory device of claim 2, wherein the first subset of the plurality of memory cells have respective threshold voltages that are less than the program verify threshold level but greater than the pre-program verify threshold level, and wherein the second subset of the plurality of memory cells have respective threshold voltages that are less than the pre-program verify threshold level.

4. The memory device of claim 1, wherein the control logic is to perform operations further comprising:
causing a data line bias voltage to be applied to a plurality of respective bitlines corresponding to the plurality of memory cells, wherein boosting the voltage potential in the one or more pillars of the memory array corresponding to the first subset of the plurality of memory cells increases effective data line bias voltages for the first subset of the plurality of memory cells.

5. The memory device of claim 4, wherein boosting the voltage potential in the one or more pillars of the memory array corresponding to the first subset of the plurality of memory cells comprises:
causing a voltage signal to be applied to a wordline associated with the plurality of memory cells, the voltage signal having an intermediate magnitude; and
causing respective select gate devices at a drain side of the one or more pillars to be disabled.

6. The memory device of claim 5, wherein boosting the voltage potential in the one or more pillars of the memory array corresponding to the first subset of the plurality of memory cells further comprises:
causing the voltage signal applied to the wordline to be ramped up to a pass voltage magnitude;
causing a first subset of the plurality of bitlines associated with the first subset of the plurality of memory cells to be driven with a high voltage, wherein the high voltage is greater than the data line bias voltage, and a second subset of the plurality of bitlines associated with the second subset of the plurality of memory cells to be driven with the data line bias voltage; and
causing the respective select gate devices to be re-enabled.

7. The memory device of claim 6, wherein the control logic is to perform operations further comprising:
causing the voltage signal applied to the wordline to be ramped up to a program voltage magnitude corresponding to the second program pulse, wherein the effective data line bias voltages for the plurality of respective bitlines are to control respective levels of partial enablement of programming the plurality of memory cells.

8. A method comprising:
initiating a program operation on a memory array of a memory device, the memory array comprising a plurality of memory cells, and the program operation comprising a plurality of program pulses;
identifying a first subset of the plurality of memory cells and a second subset of the plurality of memory cells based on respective threshold voltages after application of a first program pulse of the plurality of program pulses; and
boosting a voltage potential in one or more pillars of the memory array corresponding to the first subset of the plurality of memory cells prior to application of a second program pulse of the plurality of program pulses.

9. The method of claim 8, wherein identifying the first subset of the plurality of memory cells and the second subset of the plurality of memory cells comprises initiating a verify phase of the program operation to determine the respective threshold voltages and comparing the respective threshold voltages to a program verify threshold level and a pre-program verify threshold level.

10. The method of claim 9, wherein the first subset of the plurality of memory cells have respective threshold voltages that are less than the program verify threshold level but greater than the pre-program verify threshold level, and wherein the second subset of the plurality of memory cells have respective threshold voltages that are less than the pre-program verify threshold level.

11. The method of claim 8, further comprising:
causing a data line bias voltage to be applied to a plurality of respective bitlines corresponding to the plurality of memory cells, wherein boosting the voltage potential in the one or more pillars of the memory array corresponding to the first subset of the plurality of memory cells increases effective data line bias voltages for the first subset of the plurality of memory cells.

12. The method of claim 11, wherein boosting the voltage potential in the one or more pillars of the memory array corresponding to the first subset of the plurality of memory cells comprises:
causing a voltage signal to be applied to a wordline associated with the plurality of memory cells, the voltage signal having an intermediate magnitude; and
causing respective select gate devices at a drain side of the one or more pillars to be disabled.

13. The method of claim 12, wherein boosting the voltage potential in the one or more pillars of the memory array corresponding to the first subset of the plurality of memory cells further comprises:
causing the voltage signal applied to the wordline to be ramped up to a pass voltage magnitude;
causing a first subset of the plurality of bitlines associated with the first subset of the plurality of memory cells to be driven with a high voltage, wherein the high voltage is greater than the data line bias voltage, and a second subset of the plurality of bitlines associated with the second subset of the plurality of memory cells to be driven with the data line bias voltage; and
causing the respective select gate devices to be re-enabled.

14. The method of claim 13, further comprising:
causing the voltage signal applied to the wordline to be ramped up to a program voltage magnitude corresponding to the second program pulse, wherein the effective data line bias voltages for the plurality of respective bitlines are to control respective levels of partial enablement of programming the plurality of memory cells.

15. A non-transitory computer-readable storage medium storing instructions that, when executed by a processing device, cause the processing device to perform operations comprising:
initiating a program operation on a memory array of a memory device, the memory array comprising a plurality of memory cells, and the program operation comprising a plurality of program pulses;
identifying a first subset of the plurality of memory cells and a second subset of the plurality of memory cells based on respective threshold voltages after application of a first program pulse of the plurality of program pulses; and
boosting a voltage potential in one or more pillars of the memory array corresponding to the first subset of the plurality of memory cells prior to application of a second program pulse of the plurality of program pulses.

16. The non-transitory computer-readable storage medium of claim 15, wherein identifying the first subset of the plurality of memory cells and the second subset of the plurality of memory cells comprises initiating a verify phase of the program operation to determine the respective threshold voltages and comparing the respective threshold voltages to a program verify threshold level and a pre-program verify threshold level.

17. The non-transitory computer-readable storage medium of claim 16, wherein the first subset of the plurality of memory cells have respective threshold voltages that are less than the program verify threshold level but greater than the pre-program verify threshold level, and wherein the second subset of the plurality of memory cells have respective threshold voltages that are less than the pre-program verify threshold level.

18. The non-transitory computer-readable storage medium of claim 15, wherein the instructions cause the processing device to perform operations further comprising:
causing a data line bias voltage to be applied to a plurality of respective bitlines corresponding to the plurality of memory cells, wherein boosting the voltage potential in the one or more pillars of the memory array corresponding to the first subset of the plurality of memory cells increases effective data line bias voltages for the first subset of the plurality of memory cells.

19. The non-transitory computer-readable storage medium of claim 18, wherein boosting the voltage potential in the one or more pillars of the memory array corresponding to the first subset of the plurality of memory cells comprises:
causing a voltage signal to be applied to a wordline associated with the plurality of memory cells, the voltage signal having an intermediate magnitude; and
causing respective select gate devices at a drain side of the one or more pillars to be disabled.

20. The non-transitory computer-readable storage medium of claim 19, wherein boosting the voltage potential in the one or more pillars of the memory array corresponding to the first subset of the plurality of memory cells further comprises:
causing the voltage signal applied to the wordline to be ramped up to a pass voltage magnitude;
causing a first subset of the plurality of bitlines associated with the first subset of the plurality of memory cells to be driven with a high voltage, wherein the high voltage is greater than the data line bias voltage, and a second subset of the plurality of bitlines associated with the second subset of the plurality of memory cells to be driven with the data line bias voltage;
causing the respective select gate devices to be re-enabled; and
causing the voltage signal applied to the wordline to be ramped up to a program voltage magnitude corresponding to the second program pulse, wherein the effective data line bias voltages for the plurality of respective bitlines are to control respective levels of partial enablement of programming the plurality of memory cells.
